(19) United States
(12) Patent Application Publication
(10) Pub. No.: US 2024/0072122 A1
(43) Pub. Date: Feb. 29, 2024

(54) SEMICONDUCTOR DEVICE AND METHOD FOR MANUFACTURING A SEMICONDUCTOR DEVICE

(71) Applicant: Infineon Technologies AG, Neubiberg (DE)

(72) Inventors: Michael Hell, Erlangen (DE); Rudolf Elpelt, Erlangen (DE); Caspar Leendertz, München (DE); Bernd Zippelius, Erlangen (DE); Dethard Peters, Höchstadt (DE)

(21) Appl. No.: 18/364,519

(22) Filed: Aug. 3, 2023

(30) Foreign Application Priority Data
Aug. 26, 2022 (DE) 102022121672.1

(51) Int. Cl. H01L 29/16; H01L 29/06; H01L 29/423; H01L 29/66; H01L 29/78

(52) U.S. Cl. CPC H01L 29/1608; H01L 29/0696; H01L 29/4236; H01L 29/66068; H01L 29/66734; H01L 29/7813

(57) ABSTRACT

A semiconductor device includes a transistor including transistor cells. Each transistor cells has a gate electrode arranged in gate trenches formed in a first portion of a silicon carbide substrate and extending in a first horizontal direction, a source region, a channel region, and a current-spreading region. The source region, channel region, and at least part of the current-spreading region are arranged in ridges patterned by the gate trenches. The transistor cells further include a body contact portion of the second conductivity type arranged in a second portion of the silicon carbide substrate and electrically connected to the channel region. The transistor cells further include a shielding region of the second conductivity type. A first portion of the shielding region is arranged below the gate trenches, respectively, and a second portion of the shielding region is arranged adjacent to a sidewall of the gate trenches, respectively.

### TECHNICAL FIELD

Examples of the present disclosure relate to semiconductor devices, in particular, to semiconductor devices comprising a transistor, and to a method of manufacturing the semiconductor device.

### BACKGROUND

Transistors, in which a gate electrode is arranged in trenches adjacent to a channel region are widely used. Attempts are being made to further improve characteristics of these transistors.

The present application is directed to a semiconductor device comprising an improved transistor which may be beneficially applied e.g. to a silicon carbide substrate.

### SUMMARY

According to an example, a semiconductor device comprises a transistor, the transistor comprising a plurality of transistor cells. Each of the transistor cells comprises a gate electrode arranged in gate trenches formed in a first portion of a silicon carbide substrate and extending in a first horizontal direction, the gate trenches patterning the first portion of the silicon carbide substrate into ridges so that each of the ridges is arranged between two neighbouring gate trenches. The transistor cell further comprises a source region of a first conductivity type, a channel region of a second conductivity type, and a current-spreading region of the first conductivity type, the source region and the channel region and at least a part of the current-spreading region being arranged in the ridges. A current path from the source region to the current-spreading region extends in a depth direction of the silicon carbide substrate. The transistor cell further comprises a body contact portion of the second conductivity type that is arranged in a second portion of the silicon carbide substrate. The second portion is adjacent to the first portion and extends in a second horizontal direction intersecting the first horizontal direction. The body contact portion is electrically connected to the channel region. The transistor cell further comprises a shielding region of the second conductivity type, a first portion of the shielding region being arranged below the gate trenches, respectively, and a second portion of the shielding region being arranged adjacent to a sidewall of the gate trenches, respectively.

According to a further example, a semiconductor device comprises a transistor, the transistor comprising a plurality of transistor cells. Each of the transistor cells comprises a gate electrode arranged in gate trenches formed in a first portion of a silicon carbide substrate and extending in a first horizontal direction, the gate trenches patterning the first portion of the silicon carbide substrate into ridges so that each of the ridges is arranged between two neighbouring gate trenches. The transistor cell further comprises a source region of a first conductivity type, a channel region of a second conductivity type, and a current-spreading region of the first conductivity type, the source region, and the channel region and at least a part of the current-spreading region being arranged in the ridges. A current path from the source region to the current-spreading region extends in a depth direction of the silicon carbide substrate. The transistor cell further comprises a body contact portion of the second conductivity type that is arranged in a second portion of the silicon carbide substrate. The second portion is adjacent to the first portion and extends in a second horizontal direction intersecting the first horizontal direction. The body contact portion is electrically connected to the channel region. The transistor cell further comprises a shielding region of the second conductivity type arranged below the gate trenches, a width of the shielding region being more than 0.75× (times) the width of the gate trench, the width being measured in a direction perpendicular to the first direction. The transistor cell further comprises a source contact arranged in the second portion of the silicon carbide substrate adjacent to the ridge and in contact with the source region. A width of the source contact is larger than a width of the ridge, the width being measured in a horizontal direction perpendicular to the first horizontal direction.

According to a further example, a semiconductor device comprises a transistor comprising a plurality of transistor cells. Each of the transistor cells comprises a gate electrode arranged in gate trenches formed in a silicon carbide substrate. The gate trenches extend along a hexagon like or trapezoid like path and form a grid, the gate trenches enclosing a first mesa, respectively, so that the gate electrode is adjacent to each side of the first mesa. The transistor cell further comprises a source region of a first conductivity type, a channel region of a second conductivity type, and a current-spreading region of the first conductivity type, the source region, and the channel region and at least a part of the current-spreading region being arranged in the first mesa. A current path from the source region to the current-spreading region extends in a depth direction of the silicon carbide substrate. The transistor cell further comprises a shielding region of the second conductivity type, the shielding region being arranged below the gate trenches.

An example of a method for manufacturing a semiconductor device comprises forming a plurality of gate trenches in a first portion of a silicon carbide substrate, and forming shielding regions of a second conductivity type. Forming the shielding regions comprises a first ion implantation process, wherein ions are implanted in a bottom portion of the gate trenches to form first portions of the shielding regions, and a second ion implantation process, wherein ions are implanted via a sidewall of the gate trenches to form second portions of the shielding regions. The method further comprises forming a source region of a first conductivity type, a channel region of the second conductivity type, and a current-spreading region of the first conductivity type. The source region, the channel region and at least a part of the current-spreading region are formed in a substrate portion between adjacent gate trench segments. A current path from the source region to the current-spreading region extends in a depth direction of the silicon carbide substrate.

### BRIEF DESCRIPTION OF THE DRAWINGS

The accompanying drawings are included to provide a further understanding of the embodiments and are incorporated in and constitute a part of this specification. The drawings illustrate embodiments of a silicon carbide device and a method of manufacturing a silicon carbide device and together with the description serve to explain principles of the embodiments. Further embodiments are described in the following detailed description and the claims.

FIG. 1A shows a schematic horizontal cross-sectional view of a semiconductor device according to an example.

FIG. 1B shows a vertical cross-sectional view of an example of a semiconductor device.

FIG. 1C shows a vertical cross-sectional view of the semiconductor device taken at a different position.

FIG. 1D shows a vertical cross-sectional view of a further example of a semiconductor device.

FIG. 1E shows a cross-sectional view of the semiconductor device taken at a different position.

FIGS. 2A and 2B show vertical cross-sectional views of a semiconductor device according to a further example.

FIG. 3A shows a schematic horizontal cross-sectional view of a semiconductor device according to a further example.

FIGS. 3B and 3C show a vertical cross-sectional view of the semiconductor device taken at different positions.

FIGS. 3D and 3E show vertical cross-sectional views of the semiconductor device taken at different positions.

FIGS. 4A and 4B show vertical cross-sectional views of the semiconductor device according to a further example.

FIG. 5A shows a horizontal cross-sectional view of a semiconductor device according to a further example.

FIG. 5B shows a vertical cross-sectional view of the semiconductor device.

FIGS. 6A to 6C show horizontal cross-sectional views of semiconductor devices according to further examples.

FIG. 6D shows a vertical cross-sectional view of the semiconductor device.

FIGS. 7A to 7E show vertical cross-sectional views of a workpiece after performing processing steps for manufacturing a semiconductor device according to an example.

FIG. 8 summarizes a method according to an example.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a≤y≤b. A parameter y with a value of at least c reads as c≤y and a parameter y with a value of at most d reads as y≤d.

The term “on” is not to be construed as meaning only “directly on”. Rather, if one element is positioned “on” another element (e.g., a layer is “on” another layer or “on” a substrate or semiconductor body), a further component (e.g., a further layer) may be positioned between the two elements (e.g., a further layer may be positioned between a layer and a substrate if the layer is “on” said substrate).

Throughout the present specification elements of transistor cells of a field effect transistor are described. Generally, the field effect transistor may comprise a plurality of transistor cells that are connected in parallel. For example, each single transistor cell may comprise a single gate electrode, a single channel region and further components. The gate electrodes of the single transistor cells may be connected, e.g. electrically connected and/or formed of the same materials. For example, the gate electrodes of the single transistor cells may be connected to a common terminal, e.g. a gate terminal. Further components of the single transistor cells, e.g. the source regions may be respectively connected to a common source terminal. Still further components of the single transistor cells, e.g. the drift region, may be shared among at least some of the transistor cells. The present specification mainly describes the function and structure of the single transistor cells. As is to be readily understood, this description may likewise apply to the further single transistor cells. Descriptions merging the general elements of the transistor and the structural implementation by means of elements of the single transistor cells such as “a gate electrode arranged in gate trenches” are intended to mean that single gate electrodes of respective transistor cells are arranged in respective gate trenches.

An example of a semiconductor device comprises a transistor. The transistor comprises a plurality of transistor cells. Each of the transistor cells comprises a gate electrode arranged in gate trenches formed in a first portion of a silicon carbide substrate and extending in a first horizontal direction. The gate trenches pattern the silicon carbide substrate into ridges. The ridges are arranged between two neighbouring gate trenches, respectively.

The semiconductor device may further comprise a source region of a first conductivity type, a channel region of a second conductivity type, and a current-spreading region of the first conductivity type. The source region, the channel region and a part of the current-spreading region are arranged in the ridges.

A current path from the source region to the current-spreading region may extend in a depth direction of the silicon carbide substrate. For example, the depth direction may correspond to a vertical direction e.g. the z-direction. According to further embodiments, the depth direction may be a direction different from the vertical direction. Generally, the depth direction is a direction different from a lateral or horizontal direction. For example, the depth direction may have a component which is perpendicular to the lateral direction or to a main surface of the silicon carbide substrate. For example, the depth direction may be slanted with respect to the vertical direction.

Each of the transistor cells further comprises a body contact portion of the second conductivity type that is arranged in a second portion of the silicon carbide substrate. The second portion is adjacent to the first portion. The second portion of the silicon carbide substrate extends in a second horizontal direction intersecting the first horizontal direction. The body contact portion is electrically connected to the channel region. For example, the body contact portion may be directly adjacent to the current-spreading region.

Each of the transistor cells further comprises a shielding region of the second conductivity type. A first portion of the shielding region may be arranged below the gate trenches, respectively. Further, a second portion of the shielding region may be arranged adjacent to a sidewall of the gate trenches.

For example, the shielding region, e.g. the first portion and/or the second portion of the shield region may be electrically connected with the body contact portion.

The shielding region may contribute to shielding a gate dielectric against an electric potential that may be applied at the back side of the silicon carbide body. In a blocking mode of the silicon carbide device, the shielding region may reduce the electric field in the gate dielectric and may thus contribute to increasing device reliability.

For example, the source region may further be arranged in the second portion of the silicon carbide substrate. In this case, a conductive channel formed in the channel region may also extend in the second portion of the silicon carbide substrate. Accordingly, the channel width may be increased in comparison to cases in which the source region is not arranged in the second portion of the silicon carbide substrate. For example, in the second portion of the silicon carbide substrate, the source region may be arranged below the body contact portion.

For example, a width of the first portion of the shielding region may be larger than 0.75× (times) the width of the gate trenches. The width is measured in a second horizontal direction intersecting the first horizontal direction. For example, the shielding region may extend below a major part of the gate trench. For example, this may be accomplished due to the specific doping method in which the first portion of the shielding region may be manufactured by doping through the gate trenches.

Further, a width of the second portion of the shielding region may be smaller than 300 nm, the width being measured in the second horizontal direction. For example, such a small width may be accomplished by using an implantation via a sidewall of the gate trench.

For example, the gate electrode may continuously extend along a plurality of first and second portions of the silicon carbide substrate. In this case, the gate electrode may implement a continuous gate electrode that extends across the semiconductor device.

According to a further example, the semiconductor device may further comprise a superjunction structure of the second conductivity type extending to a larger depth than a bottom side of the current-spreading region. Such a superjunction structure further increases the voltage robustness of the device. Such a superjunction structure allows for a reduced drift-zone resistance while maintaining the same breakdown voltage V_{br}. For example, the superjunction structure may extend parallel to the gate trenches. For example, in such a case, the superjunction structure may be arranged in the first portion of the silicon carbide substrate and in the second portion of the silicon carbide substrate.

According to further examples, the superjunction structure may extend in a direction that intersects the first direction.

According to a further example, a semiconductor device comprises a transistor. The transistor comprises a plurality of transistor cells. Each of the transistor cells comprises a gate electrode arranged in gate trenches formed in a first portion of the silicon carbide substrate and extending in a first horizontal direction. The gate trenches pattern the first portion of the silicon carbide substrate into ridges so that each of the ridges is arranged between two neighboring gate trenches.

The transistor cell further comprises a source region of the first conductivity type, a channel region of a second conductivity type, and a current spreading region of the first conductivity type. The source region, the channel region and at least a part of current spreading region are arranged in the ridges. A current path from the source region to the current-spreading region extends in the depth direction of the silicon carbide substrate.

Each of the transistor cells further comprises a body contact portion of the second conductivity type that is arranged in a second portion of the silicon carbide substrate. The second portion is adjacent to the first portion. The second portion of the silicon carbide substrate extends in a second horizontal direction intersecting the first horizontal direction. The body contact portion is electrically connected to the channel region. The body contact portion may be directly adjacent to the current-spreading region.

The transistor cells further comprise a shielding region of the second conductivity type arranged below the gate trenches. A width of the shielding region is more than 0.75× the width of the gate trench, wherein the width is measured in a direction perpendicular to the first direction.

Each of the transistor cells further comprises a source contact arranged in the second portion of the silicon carbide substrate adjacent to the ridge and in contact with the source region. A width of the source contact is larger than a width of the ridge, wherein the width is measured in a horizontal direction perpendicular to the first horizontal direction.

Due to the larger width of the source contact in comparison with the width of the ridge, the contact resistance may be reduced.

For example, the gate trenches may be segmented, so that an intermediate portion is arranged between two neighboring gate trench segments along the first direction. The intermediate portion is arranged in the second portion of the silicon carbide substrate. Accordingly, the gate electrode may be absent from the second portion of the silicon carbide substrate. For example, the intermediate portion may comprise a doped portion of the second conductivity type. The doped portion of the second conductivity type may be electrically connected to the channel region. Further, the doped portion of the second conductivity type may be adjacent to the gate trench. In this manner, the gate-source capacitance may be increased and a parasitic turn-on may be suppressed. To be more specific, the capacitor formed between the doped portion of the second conductivity type and the gate trench may suppress a parasitic turn-on.

For example, a portion of the gate electrode may be arranged over the ridges to connect adjacent gate trench segments along the second direction. In more detail, a portion of the gate electrode may be arranged over the source region. The portion of the gate electrode is insulated from the source region by means of the gate dielectric. Due to this feature, the conductivity of the source region may be increased and the current from the source contacts may be distributed into the gate regions.

According to a further example, the semiconductor device may further comprise a superjunction structure of the second conductivity type extending to a larger depth than a bottom side of the current-spreading region. Such a superjunction structure further increases the voltage robustness of the device. Such a superjunction structure allows for a reduced drift-zone resistance while maintaining the same breakdown voltage V_{br}. For example, the superjunction structure may extend parallel to the gate trenches. For example, in such a case, the superjunction structure may be arranged in the first portion of the silicon carbide substrate and in the second portion of the silicon carbide substrate.

According to further examples, the superjunction structure may extend in a direction that intersects the first direction.

According to a further example, a semiconductor device comprises a transistor, the transistor comprising a plurality of transistor cells. Each of the transistor cells comprises a gate electrode arranged in gate trenches formed in a silicon carbide substrate. The gate trenches extend along a hexagon like or a trapezoid like path and form a grid. The gate trenches enclose or surround a first mesa, respectively, so that the gate electrode is adjacent to each side of the first mesa.

The transistor cell further comprises a source region of a first conductivity type, a channel region of a second conductivity type, and a current-spreading region of the first conductivity type. The source region, the channel and at least a part of the current-spreading region are arranged in the first mesa. A current path from the source region to the current-spreading region extends in a depth direction of the silicon carbide substrate.

The transistor cell further comprises a shielding region of the second conductivity type. The shielding region is arranged below the gate trenches. For example, the shielding region may be electrically connected to a source metal layer via a contact portion that is arranged adjacent to a sidewall of the gate trenches.

As has been described above, the gate trenches do not extend in one single direction but extend in at least two different directions so as to form a hexagon like or a trapezoid like path. For example, the term “hexagon like path” is intended to define a path along a hexagon-like structure, e.g. a hexagon having rounded corners. For example, the term “trapezoid like path” is intended to define a path along a trapezoid like structure. Such a structure may e.g. a square, a square having rounded corners, a rectangle, a rectangle having rounded corners and any other structure having 4 corners or 4 rounded corners.

The expression “forming a grid” is intended to mean that a web-like structure is formed so that a plurality of mesas having an identical shape or contour may be arranged in a pattern formed by the gate trenches. According to examples, the gate trenches form a connected network. In the connected gate network, the gate electrode may be connected with a gate pad by gate runners. For example, also the shielding region that is arranged below the gate trenches may form a connected network. As a consequence, contacting the network of the shielding regions may be simplified and the area needed may be reduced. Further, due to this layout, the channel density may be increased.

A doping profile of mesas enclosed by the grid may differ. For example, the gate trenches may enclose or surround a first mesa and a second mesa wherein a doped contact portion of the second conductivity type for electrically contacting the shielding region is arranged in the second mesa.

For example, each of the transistor cells may further comprise a body contact portion of the second conductivity type. The body contact portion may be electrically connected to the channel region. For example, in a cross-section perpendicular to the depth direction slightly above the channel region, the body contact portion may be arranged in a central portion of the first mesa and the source region may be arranged in an edge portion of the first mesa adjacent to the gate trenches. For example, in a further horizontal cross-section, the position of the body contact portion may be adjacent to the gate trench. The body contact portion may be arranged above the channel region.

According to further examples, the source region and a doped contact portion of the second conductivity type for contacting the shielding region may be arranged in the first mesa.

As has been described, due to the specific structure of the shielding region, beneficial effects may be achieved. For example, the entire bottom portion of the gate trench may be embedded into the shielding region. As a result, field-crowding at the trench corner is avoided or at least reduced. Consequently, the electric field in the gate oxide in a blocking state may be reduced. Further, the gate-drain capacitance may be reduced which leads to lower switching losses and helps to suppress a parasitic turn on.

Further, a shielding region as described above also helps to reduce the DIBL (“drain induced barrier lowering”) and thus a shortening of the channel length may be possible. This may be especially beneficial for low voltage classes. The reduced DIBL and a well-defined width of the current-spreading region may also be helpful to reduce the saturation current and thus to increase the short-circuit withstand time.

According to examples, a method for manufacturing a semiconductor device may comprise forming a plurality of gate trenches in a first portion of a silicon carbide substrate. The method may further comprise forming shielding regions of a second conductivity type, wherein forming the shielding regions comprises a first ion implantation process, wherein ions are implanted via a sidewall of the gate trenches to form second portions of the shielding regions. The method may further comprise forming a source region of a first conductivity type, a channel region of the second conductivity type, and a current-spreading region of the first conductivity type. The source region and the channel region and at least a part of the current-spreading region may be formed in a substrate portion between adjacent gate segments. A current path from the source region to the current-spreading region may extend in a depth direction of a silicon carbide substrate.

Accordingly, the shielding region may be formed in a self-aligned manner. As a consequence, the shielding region may overlap with the entire trench bottom. Since implantation is accomplished through the gate trenches, a lower implantation energy may be used. As a consequence, a lateral profile of the implanted portion of the second conductivity type is much sharper. In this way, a width of the current-spreading region may be defined to be more narrow and, consequently, a width of the ridges measured in a second horizontal direction may be narrowed and set to an arbitrary value. If a width of the current-spreading region and, hence, a drift region is made narrow, in a blocking state a quasi-1D electric field distribution in the drift region may be achieved. This increases the breakdown voltage and, in turn, allows for a larger doping concentration of the drift region. As a result Rₒₙ*A may be reduced for larger voltage classes and temperatures.

For example, the gate trenches may be formed to extend in a first horizontal direction. The gate trenches may be formed so as to pattern the first portion of the silicon carbide substrate into ridges so that each of the ridges is arranged between two neighboring gate trenches. The source region, the channel region and at least a part of the current-spreading region may be formed in the ridges.

According to a further example, the gate trenches may be formed to extend along a hexagon like or trapezoid like path and form a grid. The gate trenches may be formed to enclose or surround a first mesa, respectively, so that the gate electrode is adjacent to each side of the first mesa. Further, the source region and the channel region and at least a part of the current spreading region may be arranged in the first mesa.

The term “ridge” as employed within this disclosure is intended to mean a structure, e.g. a mesa, comprising two sidewalls and a top portion between the sidewalls. The sidewalls extend in a depth direction. For example, the sidewalls may be slanted with respect to a vertical direction. According to further interpretations, the term “ridge” may also be understood to implement a “fin”. Since the channel of the transistor is arranged within the ridge, the transistor is also referred to as a “FinFET”.

Transistors described herein may specifically include IGFETs (“insulated gate field effect transistor”). IGFETs are voltage controlled devices including MOSFETs (“metal oxide semiconductor FETs”) and other FETs comprising gate electrodes based on doped semiconductor material and/or comprising gate dielectrics that are or are not exclusively based on an oxide. As is to be clearly understood, further transistors may relate to IGBTs (“insulated gate bipolar transistor”).

The gate electrode may be insulated from the channel region and the current-spreading region. For example, the gate electrode may be insulated from the channel region and the current-spreading region by means of a gate dielectric such as e.g. silicon oxide, silicon nitride or a combination of these materials. According to further examples, any other dielectric material, e.g. a high-k dielectric may be used.

As described herein, the semiconductor substrate may be a silicon carbide (SiC) substrate. According to an example, the silicon carbide substrate may have a hexagonal crystal lattice with a c-plane and further main planes. The further main planes may include a-planes or m-planes.

The c-plane is a {0001} lattice plane. The further main planes may include a-planes ({11−20} family of lattice planes) and m-planes ({1−100} family of lattice planes). The a-planes include the six differently oriented lattice planes (11−20), (1−210), (−2110), (−1−120), (−12−10), and (2−1−10). The m-planes include the six differently oriented lattice planes (1−100), (10−10), (01−10), (−1100), (−1010), and (0−110).

The mean surface plane of the silicon carbide substrate may be tilted to the c-plane by an off-axis angle. In other words, the c-axis may be tilted to the vertical direction by the off-axis angle. The off-axis angle may be in a range from 2 degrees to 8 degrees, for example in a range from 3 degrees to 5 degrees. In particular, the off-axis angle may be approximately 4 degrees. For example, the c-axis may be tilted such that a plane spanned by the vertical direction and the c-axis is parallel to a {11−20}> plane. According to another example, the c-axis may be tilted such that a plane spanned by the vertical direction and the c-axis is parallel to a {1−100} plane. At the back side of the silicon carbide substrate, a second main surface of the silicon carbide substrate may extend parallel or approximately parallel to the mean surface plane at the front side.

A first main surface at a front side of the silicon carbide substrate may be planar or ribbed. A mean surface plane of the first main surface extends along the horizontal directions. The mean surface plane of a planar first main surface is identical with the planar first main surface. The mean surface plane of a ribbed first main surface is defined by the planar least squares plane of the ribbed first main surface. Position and orientation of the planar least squares plane are defined such that the sum of the squares of the deviations of surface points of the ribbed first main surface from the planar least squares plane has a minimum.

The silicon carbide substrate may horizontally extend along a plane spanned by the horizontal directions. Accordingly, the silicon carbide body may have a surface extension along two horizontal directions and may have a thickness along a vertical direction perpendicular to the horizontal directions. In other words, the vertical direction is parallel to a surface normal onto the mean surface plane.

The gate trenches may pattern the first portion of the silicon carbide substrate into ridges. By way of example, at least one of the sidewalls of the gate trenches and the ridges may be parallel to the (1−100) or the (−1100) planes.

The terms “first horizontal direction” and “second horizontal direction” define intersecting horizontal directions. Although some of the figures show—by way of illustration—the x-direction and the y-direction as examples of the first and the second horizontal directions, it is clearly to be understood, that the first horizontal direction and the second horizontal direction do not need to be perpendicular to each other. The term “depth direction” defines a direction having a component perpendicular to the mean surface plane. The term “depth direction” encompasses the vertical direction and any other direction different from a horizontal direction.

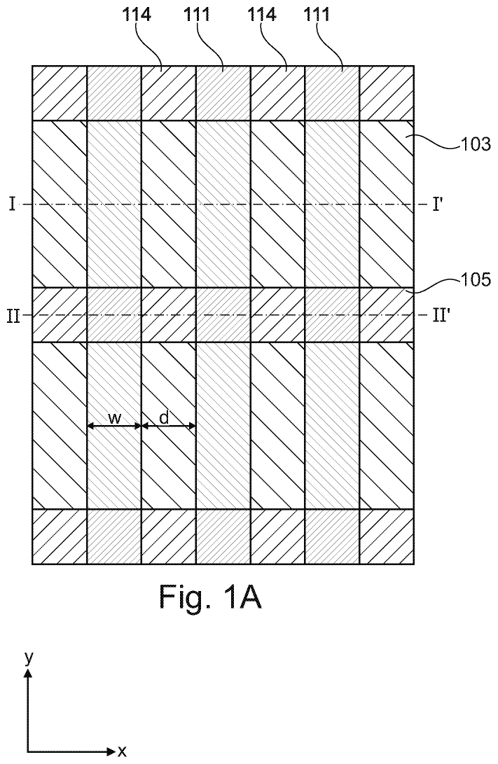

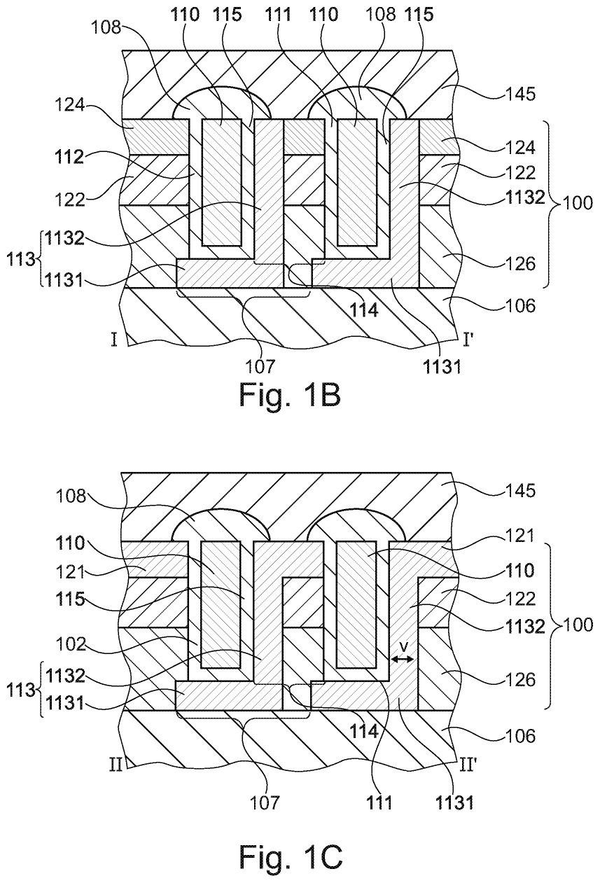

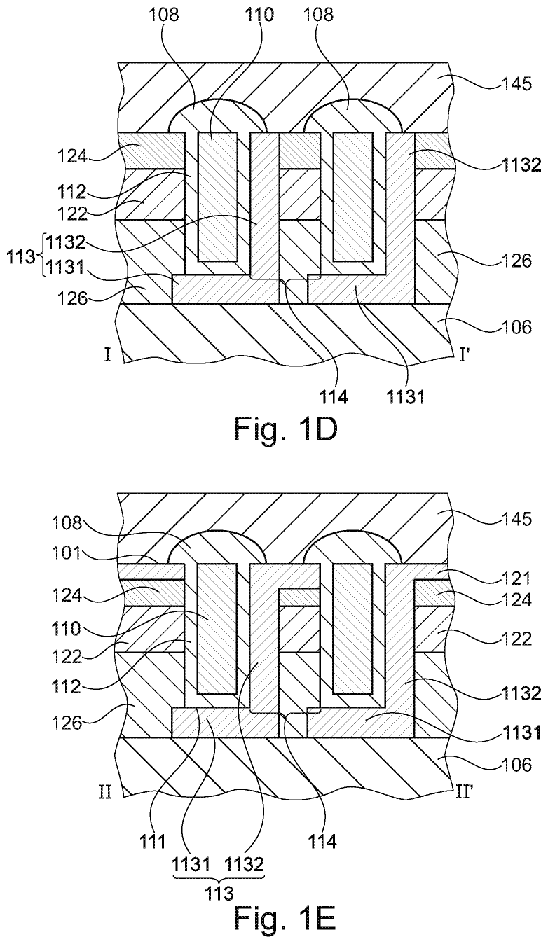

FIG. 1A shows a schematic horizontal cross-sectional view of a semiconductor device according to an example. The cross-sectional view of FIG. 1A is taken along the x-y plane. As is shown, gate trenches 111 extend in a first horizontal direction, e.g. the y-direction. Further, ridges 114 are arranged between two neighboring gate trenches 111. First portions 103 and second portions 105 of the silicon carbide substrate are alternatingly arranged along the y-direction. The first portion 103 may have a larger extension length in the second direction than in the first direction. Further, the second portion 105 has a larger extension length in the second direction than in the first direction. The first portion 103 may have a larger extension length in the first direction than the second portion 105. The gate trenches 111 may have a width w. Moreover, the distance between neighboring gate trenches 111 is denoted as “d”. The width of the ridges 114 may be equal to d.

FIG. 1B shows a vertical cross-sectional view of an example of a semiconductor device. The cross-sectional view of FIG. 1B may be taken between I and I′, as is e.g. illustrated in FIG. 1A. The cross-sectional view of FIG. 1B is taken in the first portion of the silicon carbide substrate along the second direction so as to intersect a plurality of gate trenches 111.

As is illustrated in FIG. 1B, gate trenches 111 are arranged in a silicon carbide substrate 100. For example, the silicon carbide substrate 100 may comprise a doped portion of the first conductivity type that may e.g. implement the drift region 106. A current-spreading region 126 of the first conductivity type, e.g. having a higher doping concentration than the drift region 106, may be arranged over the drift region 106. A channel region 122 of a second conductivity type may be arranged over the current-spreading region 126. A source region 124 of the first conductivity type may be arranged over the channel region 122. The source region 124 may have a higher doping concentration than the current-spreading region 126. The gate trenches 111 pattern the silicon carbide substrate 100 into ridges 114. A gate electrode 110 is arranged in the gate trenches 111. The gate electrode 110 is insulated from adjacent semiconductor material by means of a gate dielectric 112. A shielding region 113 of the second conductivity type may comprise a first portion 1131 and a second portion 1132. The first portion 1131 of the shielding region is arranged below the gate trenches 111, and may be embedded by the current-spreading region 126. The second portion 1132 of the shielding region 113 is arranged adjacent to a sidewall 115 of the gate trenches 111. The first portion 1131 and the second portion 1132 of the shielding region 113 are in direct contact and are electrically connected.

As is illustrated in FIG. 1B, the second portion 1132 of the shielding region 113 is arranged adjacent to one sidewall of the gate trench 111, whereas the source region 124 and the channel region 122 are arranged adjacent to an opposing sidewall of the gate trench 111. The source metal layer 145 may be arranged over the semiconductor substrate 100. The source metal layer 145 may be insulated from the gate electrode 110 by means of an interlayer dielectric 108. The source metal layer 145 is electrically connected to the source region 124. The source metal layer 145 may be in direct contact with the source region 124. The cross-sectional view of FIG. 1B shows two transistor cells 107. For example, a width v of the second portion 1132 of the shielding region 113 may be smaller than 300 nm, the width v being measured in the second horizontal direction.

FIG. 1C shows a vertical cross-sectional view of the semiconductor device between II and II′, as is also indicated in FIG. 1A. The cross-sectional view of FIG. 1C is taken in the second portion 105 of the silicon carbide substrate 100 and extends along the second horizontal direction. As is shown, the gate trenches 111 extend across the second portion 105. The components arranged in the second portion 105 of the semiconductor substrate 100 basically correspond to those illustrated in FIG. 1B. Differing from the cross-sectional view of FIG. 1B, according to an example, the source region 124 is not arranged in the second portion 105 of the silicon carbide substrate. Instead, a body contact portion 121 of the second conductivity type is arranged adjacent to a main surface of the silicon carbide substrate 100. The body contact portion 121 electrically connects the channel region 122 with the source metal layer 145. Moreover, the body contact portion 121 electrically connects the shielding region 113 with the source metal layer 145.

FIG. 1D shows a cross-sectional view of the semiconductor device 10 according to a further example. The cross-sectional view of FIG. 1D is taken between I and I′ as is also indicated in FIG. 1A. As is illustrated, in the first portion 103 of the silicon carbide substrate, the cross-sectional view is identical to the cross-sectional view of FIG. 1B.

FIG. 1E shows a vertical cross-sectional view of the semiconductor device between II and II′, as is also indicated in FIG. 1A. As is illustrated in FIG. 1E, the source region 124 is also present in the second portion 105 of the silicon carbide substrate. In more detail, the source region 124 may be arranged between the channel region 122 and the body contact portion 121. The body contact portion 121 may be arranged adjacent to the first main surface 101 of the silicon carbide substrate. Further, the source region 124 is arranged at a distance to the first main surface 101 of the silicon carbide substrate 100. Due to the presence of the source region 124, a conductive channel may be formed in the channel region 122 in the second portion 105 of the silicon carbide substrate 100. Accordingly, the channel width may be increased in comparison to the semiconductor device illustrated in FIGS. 1B and 1C.

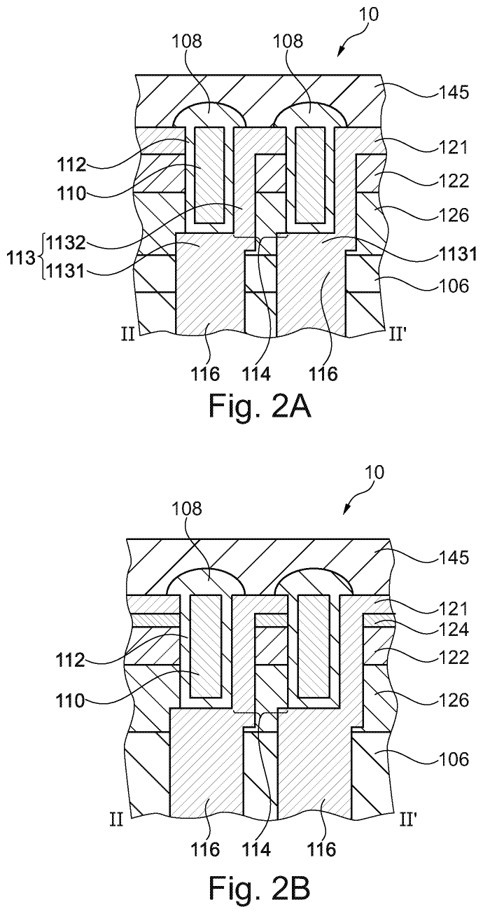

FIG. 2A shows a cross-sectional view of a semiconductor device between II and II′ according to a further example similar to FIG. 1E. The cross-sectional view of FIG. 2A is taken between II and II′, i.e. in the second portion 105 of the silicon carbide substrate. As is shown, a doped portion of the second conductivity type extends in the depth direction to a region below the current spreading region 126. The doped portion implements a superjunction structure 116. The superjunction may extend along the first direction and may be arranged below the gate trenches 111. Alternatively, the superjunction structure 116 may be arranged in a direction intersecting the first direction.

FIG. 2B shows a semiconductor device similar to the semiconductor device illustrated in FIG. 1D. In addition, the semiconductor device 10 comprises a superjunction structure 116 which has been explained with reference to FIG. 2A. Alternatively, the superjunction structure 116 may be arranged in a direction intersecting the first direction.

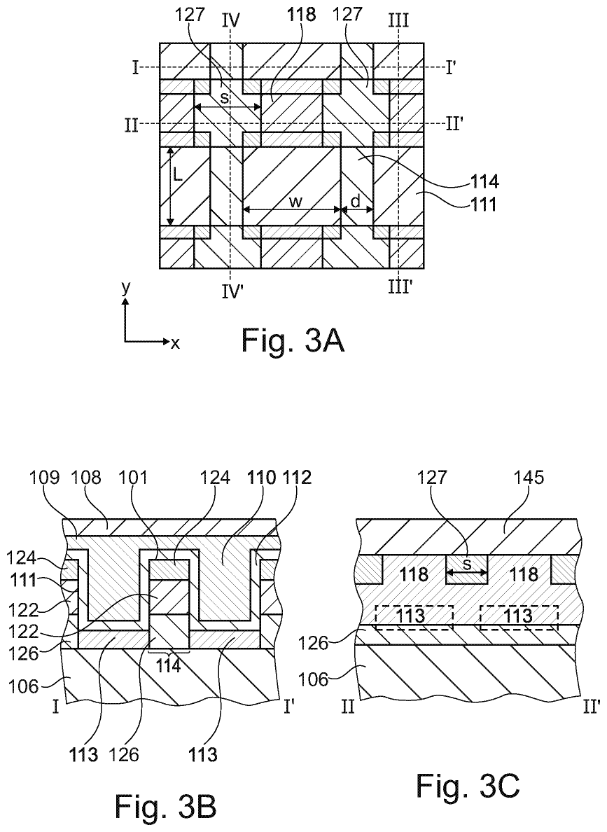

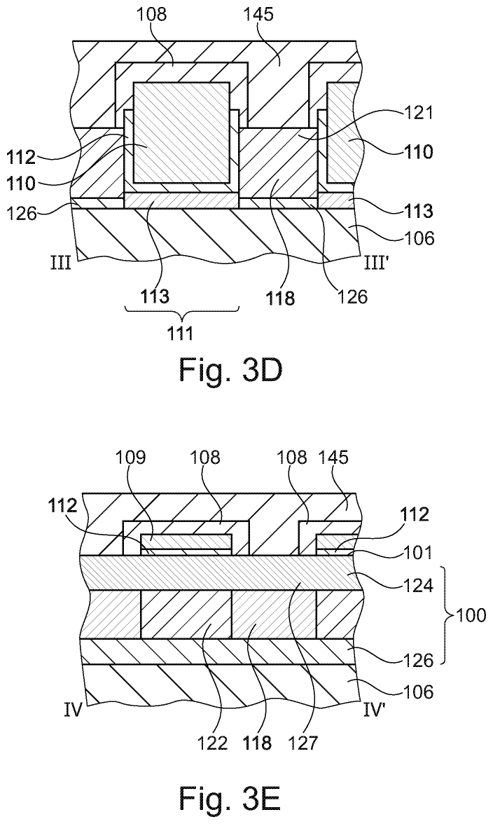

FIG. 3A shows a horizontal cross-sectional view of a semiconductor device according to further examples. Differing from the semiconductor device described with reference to FIGS. 1A to 1E, the gate trenches 111 are segmented, so that they are not formed as continuous lines extending along the first direction. As will be explained later, an intermediate material may be arranged between adjacent segments of the gate trenches. The intermediate portion 118 comprises a semiconductor material of the second conductivity type. Further, the ridges 114 are arranged between adjacent segments of gate trenches 111. A width w of the gate trenches 111 measured in the second horizontal direction may be larger than a distance d between adjacent gate trenches 111.

FIG. 3B shows a cross-sectional view of the semiconductor device between I and I′ as is also illustrated in FIG. 3A. The cross-sectional view of FIG. 3B is taken in a portion in which gate trenches 111 are present. Compared with the semiconductor device illustrated in FIGS. 1A to 1B, the ratio of the width w of the gate trenches 111 to distance d between adjacent gate trenches is larger in FIG. 3B than e.g. in FIG. 1B. The gate trenches 111 are formed in a semiconductor substrate 100. A drift region 106 of the first conductivity type, a current-spreading region 126 of the first conductivity type, a channel region 122 of the second conductivity type, and a source region 124 of the first conductivity type are formed in a ridge 114 between adjacent gate trenches 111. The source region 124 may be arranged adjacent to a first main surface 101 of the ridge 114.

A shielding region 113 is arranged below the gate trenches 111. The width of the shielding portion 113 is larger than 0.75*the width of the gate trench 111. As is further shown in FIG. 3B, the gate electrodes 110 of adjacent gate trenches are electrically connected by means of the electrically conductive gate electrode material which extends over the ridges 114. An interlayer dielectric 108 may be arranged over the gate electrode material.

The cross-sectional view of FIG. 3C is taken between II and II′. The cross-sectional view of FIG. 3C is taken along the second direction in a portion in which the gate trench 111 is absent. In particular, intermediate portions 118 and source contacts 127 are arranged along the second direction. The intermediate portion 118 is doped with dopants of the second conductivity type. The intermediate portion 118 electrically connects the shielding portions 113 which are arranged below the gate trenches 111 in a plane before and behind the depicted plane of the drawing. Positions of the shielding portions 113 are indicated by dotted lines. The source contact 127 has a width s measured along the second direction. The width s is larger than the distance d between adjacent gate trenches 111, illustrated in FIG. 3A. The source metal layer 145 may be arranged over the intermediate portions 118 and over the source contact 127. The source metal layer is electrically connected to the intermediate portion 118 and to the source contact 127.

FIG. 3D shows a vertical cross-sectional view which is taken along the first direction between III and III′. To be more specific, the cross-section of FIG. 3D is taken along the first direction to cut the gate trench 111. Accordingly, FIG. 3D shows segments of the gate trenches 111 and intermediate portions 118 arranged between adjacent segments of the gate trenches. The gate electrode 110 is arranged in the gate trenches 111. The gate electrode 110 is insulated by a gate dielectric 112 from adjacent semiconductor material of the intermediate portion 118. In this manner, the gate-source capacitance may be increased and a parasitic turn-on may be suppressed. To be more specific, the capacitor formed between the intermediate portion 118 of the second conductivity type and the gate trench 111 may suppress a parasitic turn-on. The intermediate portion 118 implements a body contact portion 121. The current-spreading region 126 is arranged below the body contact portion 121. The shielding region 113 is arranged below the segments of the gate trenches 111.

FIG. 3E shows a cross-sectional view which is taken along the first direction to cut a ridge 114. As is shown, channel regions 122 and intermediate portions 118 of the second conductivity type are arranged alternatingly along the first direction. A source region 124 is arranged adjacent to the first main surface 101 of the semiconductor substrate 100. In a portion of the gate trenches, the gate metal layer 109 is arranged over the source region 124. The gate metal layer 109 is insulated from the source region 124 by means of the gate dielectric 112. A source metal layer 145 is arranged over the gate metal layer 109. In a portion between adjacent segments of the gate trenches 111, the doped portion of the first conductivity type implements a source contact 127. At the position of the source contact 127 between adjacent gate trenches 111, the source metal layer 145 is arranged directly adjacent to the source contacts 127. The source metal layer 145 is electrically connected to the source region by means of source contact 127. As is further shown in FIG. 3E, the gate stripes cover the source region 124. A thin gate dielectric layer 112 is arranged between the source region 124 and the gate metal layer 109. Accordingly, the gate metal layer 109 may control the conductivity within the source region 124 via a field effect. As a consequence, the conductivity of the source region 124 may be increased and the current from the source contacts 127 may be distributed into the gate regions. For example, a width of the source regions measured in a vertical direction may be increased to further increase the conductivity of the source regions 124.

Due to the special design of the gate electrode comprising segmented portions that are connected along the second horizontal direction, the gate resistance may be independent from a width of the gate trenches 111. In more detail, the length L of the gate electrode along the first horizontal direction may be adjusted. Further, the thickness of the gate electrode 110 over the ridges 114 may be adjusted. These adjustments may set a low gate resistance. As a consequence, the internal gate resistance of the semiconductor device may be tuned. Further, the dimensioning of the implanted portions 118, 127, 124 could be utilized to form a JFET in the contacting region, as e.g. illustrated in FIG. 3C. This might be helpful to increase the short-circuit withstand time.

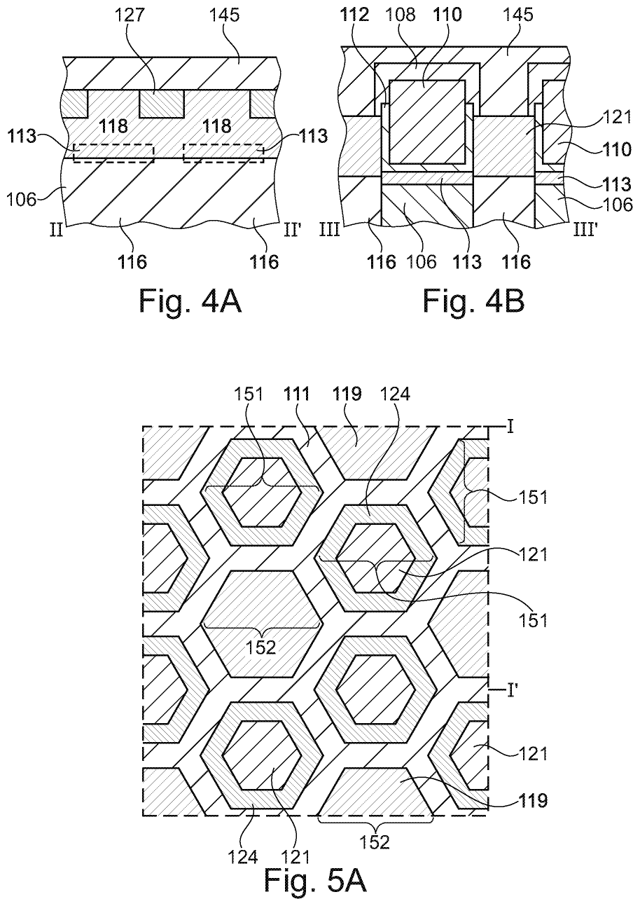

FIG. 4A shows a cross-sectional view of the semiconductor device between II and II′ according to further implementations. As is shown, the semiconductor device further comprises a superjunction structure 116 which is arranged below the shielding region 113. The superjunction structure 116 may be implemented in a corresponding manner as the superjunction structure 116 explained with reference to FIG. 2A. As is shown, differing from the implementation shown in FIG. 2A, the superjunction structure extends along the second direction. Moreover, FIG. 4B shows a cross-sectional view between III and III′, e.g. along the first direction.

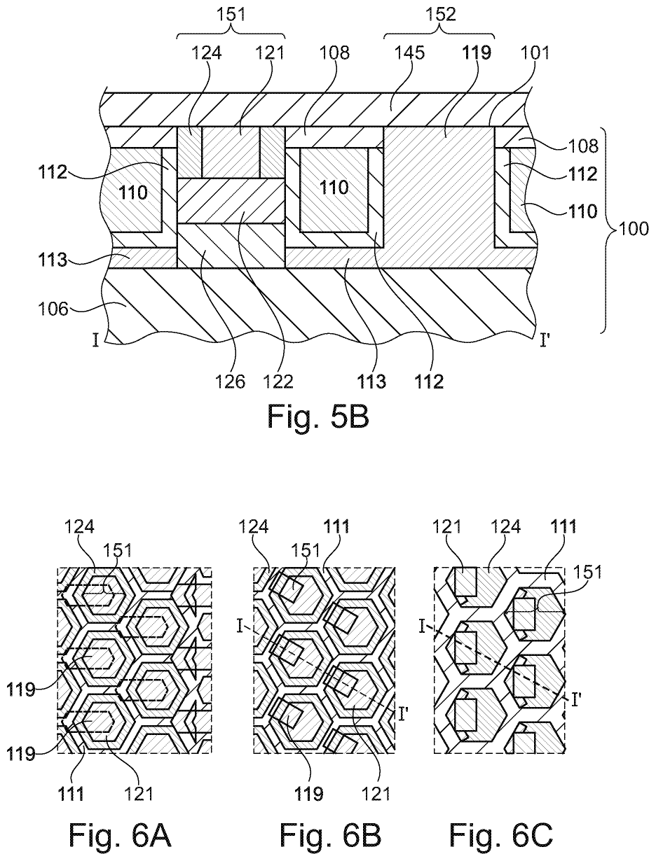

FIG. 5A shows a horizontal cross-sectional view of a semiconductor device according to further embodiments. As is illustrated, the gate trenches extend along a hexagon like path and form a grid. For example, the gate trenches 111 may run in two different directions. The gate trenches enclose or surround a first mesa 151 so that the gate electrode is adjacent to each side of the first mesa. For example, a source region 124 is arranged to each sidewall of the first mesa. A body contact portion 121 of the second conductivity type may be arranged in the central portion of the first mesa 151. The semiconductor device may further comprise second mesas 152. A contact portion 119 may be arranged in the second mesa 152.

FIG. 5B shows a vertical cross-sectional view of the semiconductor device, which may be taken between I and I′, as is also indicated in FIG. 5A.

The cross-sectional view of FIG. 5B intersects a first mesa 151 and a second mesa 152. The silicon carbide substrate 100 comprises a drift region 106 which may e.g. be of the first conductivity type. A portion of a current-spreading region 126 may be arranged over the drift region 106 in a portion of the first mesa 151. A channel region 122 of the second conductivity type is arranged over the current-spreading region 126. A source region 124 is arranged over the channel region 122. The source region 124 is disposed adjacent to a sidewall of the first mesa 151. The source region 124 is arranged adjacent to the gate trench 111. A body contact portion 121 is formed in a central portion of the first mesa 151. The body contact portion 121 is directly adjacent and electrically connected to the channel region 122.

Gate trenches 111 are arranged in the first main surface 101 of the silicon carbide substrate 100. The gate trenches 111 extend to a depth so that a shielding region 113 is arranged between a bottom side of the gate trenches 111 and the drift region 106. The shielding region 113 may be of the second conductivity type. Moreover, a contact portion 119 is arranged in the first mesa 152. The contact portion 119 extends from the first main surface 101 to a portion below the bottom region of the gate trenches 111. The contact portion 119 may electrically connect the shielding region 113 with the source metal layer 145 which is arranged over the first main surface 101 of the semiconductor substrate. As has been described, the gate trenches 111 may enclose a first mesa 151 as well as a second mesa 152. The number and the density of the second mesas 152 may be varied according to the specific needs. For example, by varying the number and the density of the second mesas 152, the gate-source capacitance and the channel density may be adjusted.

According to examples, the gate trenches 111 form a connected network. Further, the shielding region 113 that is arranged below the gate trenches may form a connected network. As a consequence, contacting the network of the shielding regions may be simplified and the area needed may be reduced.

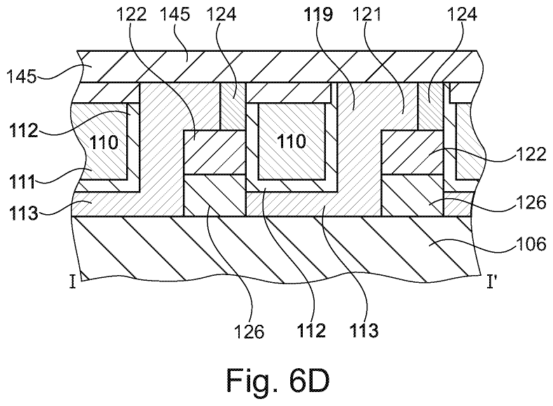

FIGS. 6A to 6C show horizontal cross-sectional views of the semiconductor device according to further examples, in which a contact portion 119 for electrically connecting the shielding region 113 to the source metal layer 145 is integrated in the mesas 151. According to examples, the contact portion 119 may be integrated in only a part of the mesas 151.

For example, as is illustrated in FIG. 6A, the contact portions 119 may be arranged asymmetrically on one side of the mesas and may electrically connect the shielding portion 113 to the source metal layer 145.

FIG. 6B shows a further configuration, in which the contact portion 119 extends in a direction which is perpendicular to a direction of the gate trench 111. Differently stated, the contact portion 119 adjoins to one edge of the hexagon.

For example, forming the contact portion 119 illustrated in FIGS. 6A and 6B may comprise using a masked trench sidewall implantation. Due to this masked trench sidewall implantation, high energies may be avoided.

FIG. 6C shows a horizontal cross-sectional view of a semiconductor device in which the shielding region 113 is connected via a doped portion 119 adjacent to one or two sidewalls of the mesa 151.

FIG. 6D shows a vertical cross-sectional view of the semiconductor device illustrated in any of FIGS. 6A to 6C. For example, the cross-sectional view of FIG. 6D may be taken between I and I′ which is e.g. indicated in FIG. 6B or 6C. As is illustrated in FIG. 6D, a shielding region 113 is arranged below each of the gate trenches 111. The shielding region 113 is connected to the source metal layer 145 by means of a contact portion 119 which is arranged adjacent to the gate trench 111. The source region 124 is arranged adjacent to one sidewall of the gate trenches 111. Further, the channel region 122 and the current-spreading region 126 are arranged adjacent to the sidewall to which the source region 124 is adjacent. The channel region 122 is arranged between the source region 124 and the current-spreading region 126. The current-spreading region 126 is arranged between the channel region 122 and the drift region 106. Accordingly, the contact portion 119 of the second conductivity type forms a step-shaped structure which extends below the gate trenches and over a part of the channel region 122 so as to reach the source metal layer 145.

In the following, a method of manufacturing a semiconductor device which has been described hereinabove will be explained.

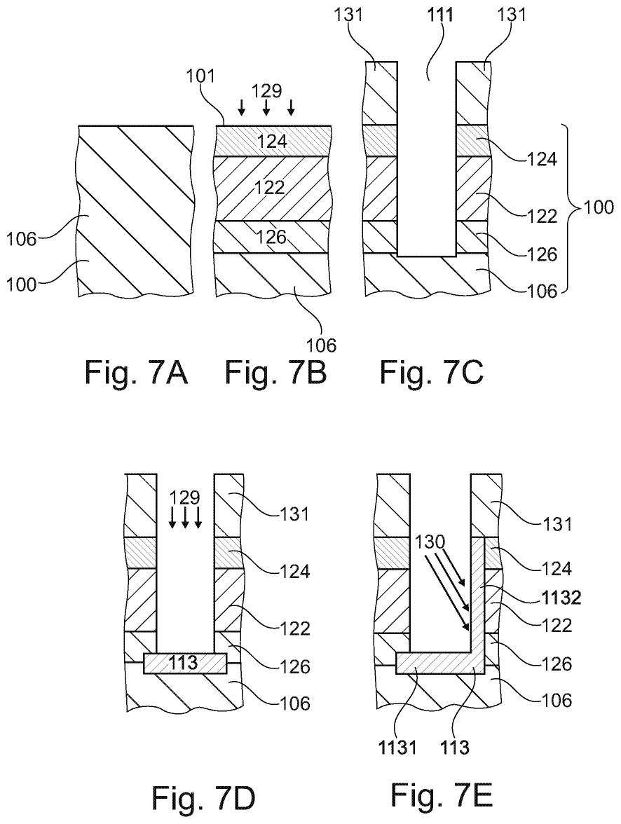

FIG. 7A shows a cross-sectional view of a silicon carbide substrate 100 which may be doped with dopants of the first conductivity type to form the drift region 106 of the semiconductor device. As is shown in FIG. 7B, ion implantation processes 129 are performed so as to form differently doped semiconductor layers. For example, a source region 124 of the first conductivity type may be formed adjacent to a first main surface 101 of the semiconductor substrate. A channel region 122 of the second conductivity type may be formed below the source region 124. Further, a current-spreading region 126 may be formed below the channel region 122.

Thereafter, referring to FIG. 7C, gate trenches are formed, e.g. by etching using a hard mask 131. A hard mask layer (stack) is formed over the workpiece and patterned to form trenches in the hard mask layer stack thereby defining the hard mask 131. Thereafter, using the hard mask 131 as an etching mask, gate trenches 111 are etched in the semiconductor substrate 100.

Thereafter (FIG. 7D), an ion implantation process 129 with dopants of the second conductivity type is performed. This ion implantation process 129 may be performed at 90° with respect to the first main surface 101. For example, a channel along the m-plane may be used. In particular, implantation is carried out without tilting against the trench sidewall. In this way, undesired doping with the second conductivity type at the trench sidewall is suppressed as much as possible. FIG. 7D shows an example of a resulting workpiece.

Thereafter (FIG. 7E), a tilted ion implantation process 130 may be performed so as to dope the sidewall of the gate trench 111. Thereby, the shielding portion 113 comprising the first and the second portions 1131, 1132 may be formed. For example, using a tilted ion implantation 130 at an angle of approximately 5° with respect to a vertical direction at energies of about 400 keV, a width of the second portion 1132 of less than 300 nm may be accomplished. A width of the first portion 1131 of the shielding region 113 may be larger than 0.75*the width of the gate trench.

According to further examples, the sequence of the tilted ion implantation process 130 and the non-tilted ion implantation process 129 may be changed. For example, the tilted ion implantation process 130 may be performed before the non-tilted ion implantation process 129.

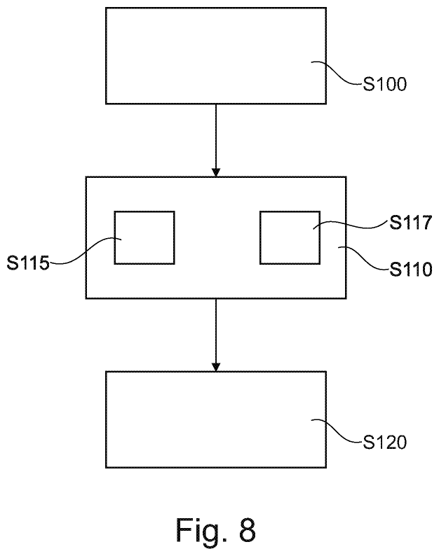

FIG. 8 summarizes a method according to embodiments.

As is shown, a method for manufacturing a semiconductor device comprises forming (S100) a plurality of gate trenches in a first portion of a silicon carbide substrate, and forming (S110) shielding regions of a second conductivity type. Forming (S110) the shielding regions comprises a first ion implantation process (S115), wherein ions are implanted in a bottom portion of the gate trenches to form first portions of the shielding regions, and a second ion implantation process (S117), wherein ions are implanted via a sidewall of the gate trenches to form second portions of the shielding regions. The method further comprises forming (S120) a source region of a first conductivity type, a channel region of the second conductivity type, and a current-spreading region of the first conductivity type, the source region, and the channel region and at least a part of the current-spreading region being formed in a substrate portion between adjacent gate trench segments, a current path from the source region to the current-spreading region extending in a depth direction of the silicon carbide substrate.

For example, forming (S120) a source region of a first conductivity type, a channel region of the second conductivity type, and a current-spreading region of the first conductivity type or parts of this processing may be performed before forming the shielding regions or before performing some or any of the ion implantations processes for forming the shielding regions.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A semiconductor device comprising a transistor, the transistor comprising a plurality of transistor cells, each of the transistor cells comprising:
a gate electrode arranged in gate trenches formed in a first portion of a silicon carbide substrate and extending in a first horizontal direction, wherein the gate trenches pattern the first portion of the silicon carbide substrate into ridges so that each of the ridges is arranged between two neighbouring gate trenches;
a source region of a first conductivity type, a channel region of a second conductivity type, and a current-spreading region of the first conductivity type, wherein the source region, the channel region, and at least a part of the current-spreading region are arranged in the ridges, wherein a current path from the source region to the current-spreading region extends in a depth direction of the silicon carbide substrate;
a body contact portion of the second conductivity type arranged in a second portion of the silicon carbide substrate, wherein the second portion is adjacent to the first portion and extends in a second horizontal direction that intersects the first horizontal direction, wherein the body contact portion is electrically connected to the channel region; and
a shielding region of the second conductivity type, wherein a first portion of the shielding region is arranged below the gate trenches, respectively, and a second portion of the shielding region is arranged adjacent to a sidewall of the gate trenches, respectively.

2. The semiconductor device of claim 1, wherein the shielding region is electrically connected with the body contact portion.

3. The semiconductor device of claim 1, wherein the source region is also arranged in the second portion.

4. The semiconductor device of claim 1, wherein a width of the first portion of the shielding region is larger than 0.75 times the width of the gate trench, the widths being measured in a second horizontal direction intersecting the first horizontal direction.

5. The semiconductor device of claim 1, wherein a width of the second portion of the shielding region is smaller than 300 nm, the width being measured in a second horizontal direction intersecting the first horizontal direction.

6. The semiconductor device of claim 1, wherein the gate electrode continuously extends along a plurality of first and second portions of the silicon carbide substrate.

7. The semiconductor device of claim 1, further comprising a superjunction structure of the second conductivity type extending to a larger depth than a bottom side of the current-spreading region.

8. A semiconductor device comprising a transistor, the transistor comprising a plurality of transistor cells, each of the transistor cells comprising:
a gate electrode arranged in gate trenches formed in a first portion of a silicon carbide substrate and extending in a first horizontal direction, wherein the gate trenches pattern the first portion of the silicon carbide substrate into ridges so that each of the ridges is arranged between two neighbouring gate trenches;
a source region of a first conductivity type, a channel region of a second conductivity type, and a current-spreading region of the first conductivity type, wherein the source region, the channel region, and at least a part of the current-spreading region are arranged in the ridges, wherein a current path from the source region to the current-spreading region extend in a depth direction of the silicon carbide substrate;
a body contact portion of the second conductivity type arranged in a second portion of the silicon carbide substrate, wherein the second portion is adjacent to the first portion and extends in a second horizontal direction intersecting the first horizontal direction, wherein the body contact portion is electrically connected to the channel region;
a shielding region of the second conductivity type arranged below the gate trenches, wherein a width of the shielding region is more than 0.75 times the width of the gate trench, the widths being measured in a direction perpendicular to the first direction; and
a source contact arranged in the second portion of the silicon carbide substrate adjacent to the ridge and in contact with the source region, wherein a width of the source contact is larger than a width of the ridge, the widths being measured in a horizontal direction perpendicular to the first horizontal direction.

9. The semiconductor device of claim 8, wherein the gate trenches are segmented so that an intermediate portion is arranged between two neighbouring trenches along the first direction, the intermediate portion being arranged in the second portion of the silicon carbide substrate.

10. The semiconductor device of claim 9, wherein the intermediate portion comprises a doped portion of the second conductivity type that is electrically connected to the channel region.

11. The semiconductor device of claim 8, wherein a portion of the gate electrode is arranged over the ridges.

12. The semiconductor device of claim 8, further comprising a superjunction structure of the second conductivity type extending to a larger depth than a bottom side of the current-spreading region.

13. A semiconductor device comprising a transistor, the transistor comprising a plurality of transistor cells, each of the transistor cells comprising:
a gate electrode arranged in gate trenches formed in a silicon carbide substrate, wherein the gate trenches extend along a hexagon like or a trapezoid like path and form a grid, wherein the gate trenches enclose a first mesa, respectively, so that the gate electrode is adjacent to each side of the first mesa;
a source region of a first conductivity type, a channel region of a second conductivity type, and a current-spreading region of the first conductivity type, wherein the source region, the channel region, and at least a part of the current-spreading region are arranged in the first mesa, wherein a current path from the source region to the current-spreading region extends in a depth direction of the silicon carbide substrate; and
a shielding region of the second conductivity type arranged below the gate trenches.

14. The semiconductor device of claim 13, wherein the gate trenches further enclose a second mesa, and wherein a doped contact portion of the second conductivity type for electrically contacting the shielding region is arranged in the second mesa.

15. The semiconductor device of claim 13, wherein each of the transistor cells further comprises a body contact portion of the second conductivity type, the body contact portion being electrically connected to the channel region, and wherein the body contact portion is arranged in a central portion of the first mesa and the source region is arranged in an edge portion of the first mesa adjacent to the gate trench.

16. The semiconductor device of claim 15, wherein the source region and a doped contact portion of the second conductivity type for electrically contacting the shielding region are arranged in the first mesa.

17. A method for manufacturing a semiconductor device comprising a transistor comprising a plurality of transistor cells, the method comprising:
forming a plurality of gate trenches in a first portion of a silicon carbide substrate;
forming shielding regions of a second conductivity type, wherein forming the shielding regions comprises a first ion implantation process, wherein ions are implanted in a bottom portion of the gate trenches to form first portions of the shielding regions, and a second ion implantation process, wherein ions are implanted via a sidewall of the gate trenches to form second portions of the shielding regions;
forming a source region of a first conductivity type, a channel region of the second conductivity type, and a current-spreading region of the first conductivity type, wherein the source region, the channel region, and at least a part of the current-spreading region are formed in a substrate portion between adjacent gate trench segments, wherein a current path from the source region to the current-spreading region extends in a depth direction of the silicon carbide substrate.

18. The method of claim 17, wherein the gate trenches are formed to extend in a first horizontal direction, the gate trenches patterning the first portion of the silicon carbide substrate into ridges so that each of the ridges is arranged between two neighbouring gate trenches, and wherein the source region, the channel region, and at least a part of the current-spreading region are formed in the ridges.

19. The method of claim 17, wherein the gate trenches are formed to extend along a hexagon like or trapezoid like path and form a grid, the gate trenches enclosing a first mesa, respectively, so that the gate electrode is adjacent to each side of the first mesa, and wherein the source region, the channel region, and at least a part of the current-spreading region are arranged in the first mesa.

20. The method of claim 17, wherein a width of the second portions of the shielding regions is smaller than 300 nm, the width being measured in the second horizontal direction.
